(19) United States
(12) Patent Application Publication
(10) Pub. No.: US 2023/0157054 A1
(43) Pub. Date: May 18, 2023

(54) DISPLAY DEVICE

(71) Applicant: LG DISPLAY CO., LTD., Seoul (KR)

(72) Inventors: YunJin NA, Gyeonggi-do (KR); Junho YEO, Gyeonggi-do (KR)

(73) Assignee: LG DISPLAY CO., LTD., SEOUL (KR)

(21) Appl. No.: 17/966,942

(22) Filed: Oct. 17, 2022

(30) Foreign Application Priority Data
Nov. 17, 2021 (KR) 10-2021-0158529

(51) Int. Cl. H01L 51/52; H01L 27/32; G06F 3/041; G06F 3/044

(52) U.S. Cl. CPC H01L 51/5253; H01L 27/323; H01L 27/3276; G06F 3/041662; G06F 3/0446; G06F 2203/04106

(57) ABSTRACT

A display device includes a substrate including a display area and a non-display area positioned outside the display area, a plurality of light emitting devices disposed in the display area, an encapsulation layer disposed on the plurality of light emitting devices and including an organic encapsulation layer, and a surrounding organic pattern disposed in the non-display area along the periphery of the organic encapsulation layer and surrounding the organic encapsulation layer, thereby preventing film lifting and moisture permeation defects caused by static electricity generated during the panel manufacturing process in advance.

### CROSS-REFERENCE TO RELATED APPLICATION

This application claims the priority of Korean Patent Application No. 10-2021-0158529, filed on Nov. 17, 2021, which is hereby incorporated by reference in its entirety.

### BACKGROUND

### Field of the Disclosure

The present disclosure relates to a display device.

### Description of the Background

As the information society develops, various types of display devices for displaying images have been developed. Among such display devices, there is a self-luminous display in which light emitting elements emitting light by themselves are formed in the display panel without a backlight unit outside the display panel.

In the case of the self-luminous display, each of a plurality of sub-pixels disposed on the display panel requires a light emitting device, several transistors for driving the light emitting device, and at least one capacitor.

Meanwhile, technology development for applying a touch-based input method that allows a user to easily and intuitively and conveniently input information or commands to the self-luminous display is in progress.

As described above, in order to apply the touch-based input method to the self-luminous display, a touch panel including a touch sensor must be separately manufactured and combined with the display panel. This method has the disadvantages of increasing the size or thickness of the device and complicating the manufacturing process. Accordingly, a technology for embedding a touch sensor in the display panel without separately manufacturing the touch panel is being developed. When the touch sensor is embedded in the display panel, the touch sensor structure may affect the display structure or the display structure may affect the touch sensor structure in the display panel.

In addition, there has been a problem in that a film lifting phenomenon occurs at the periphery of the display panel or moisture permeation occurs.

### SUMMARY

The inventors of the present disclosure have found that the outer power line is disposed at a point where the film lifting phenomenon or moisture permeation defect occurs at the periphery of the display panel, and that the film lifting occurs around the outer power line.

The inventors of the present disclosure have paid attention to the relationship between the outer power line and the occurrence of film lift. The inventors of the present disclosure have also found that the outer power line may be affected by static electricity, and thus a film lifting phenomenon or moisture permeation defect may occur around the outer power line.

Accordingly, the present disclosure is to provide a display device having a structure that can prevent film lifting and moisture permeation in advance, based on the above facts. In the present specification, a film may also be described as a layer.

Various aspects of the present disclosure provides a display device having a structure capable of blocking a film lifting phenomenon and a moisture permeation defect caused by static electricity in advance.

Various aspects of the present disclosure provides a display device capable of blocking in advance a film lifting phenomenon and a moisture permeation defect under a narrow bezel structure.

Various aspects of the present disclosure provide a display device having a structure capable of preventing the outer power line from being affected by static electricity, thereby preventing film lifting and moisture permeation around the outer power line due to static electricity in advance.

Various aspects of the present disclosure provides a display device having a structure capable of increasing insulation between a touch routing line extending from or connected to the touch sensor metal and the outer power line.

In an aspect of the present disclosure, a display device includes a substrate including a display area and a non-display area positioned outside the display area, a plurality of light emitting devices disposed in the display area, an encapsulation layer disposed on the plurality of light emitting devices and including an organic encapsulation layer, and a surrounding organic pattern disposed in the non-display area along an outer periphery of the organic encapsulation layer and surrounding all or part of the organic encapsulation layer.

In an aspect of the present disclosure, a display device includes the surrounding organic pattern that may be disposed in the non-display area along the periphery of the organic encapsulation layer, and may be a closed ring type organic layer. The surrounding organic pattern may surround the organic encapsulation layer in all directions.

Alternatively, In an aspect of the present disclosure, a display device includes the surrounding organic pattern that may be an open ring type organic layer disposed in the non-display area along the periphery of the organic encapsulation layer and surrounding the organic encapsulation layer. The surrounding organic pattern may surround a portion of the organic encapsulation layer, and may be disconnected at a circuit connection area to which an integrated circuit is bonded or electrically connected.

The display device according to an aspect of the present disclosure may further include a first dam disposed in the non-display area and positioned near an inclined surface of the encapsulation layer or outside the inclined surface of the encapsulation layer, and a second dam disposed in the non-display area and positioned outside the first dam.

In the display device according to an aspect of the present disclosure, the surrounding organic pattern may be positioned on the second inorganic encapsulation layer.

In the display device according to an aspect of the present disclosure, the surrounding organic pattern may be positioned between the first dam and the second dam.

The display device according to an aspect of the present disclosure may further include a touch sensor metal positioned on the second inorganic encapsulation layer, a touch routing line positioned on the second inorganic encapsulation layer and extending from the touch sensor metal or electrically connected to the touch sensor metal, and a touch pad unit electrically connected to a touch driving circuit and positioned outside the non-display area.

In the display device according to an aspect of the present disclosure, the touch routing line may be disposed along an inclined surface of the second inorganic encapsulation layer and is electrically connected to the touch pad unit.

In the display device according to aspects of the present disclosure, the touch routing line may overlap the surrounding organic pattern.

The display device according to an aspect of the present disclosure may further include an outer power line disposed on the substrate in the non-display area, positioned under the first dam and the second dam, and overlapping the first dam and the second dam.

The display device according to an aspect of the present disclosure may further include at least one insulating layer disposed between the surrounding organic pattern and the outer power line. The surrounding organic pattern overlaps the outer power line.

In the display device according to an aspect of the present disclosure, the outer power line may include a base voltage line for supplying a base voltage applied to a common electrode.

The display device according to an aspect of the present disclosure includes a substrate including a display area and a non-display area positioned outside the display area, a common electrode disposed on the substrate, an encapsulation layer disposed on the common electrode, a first dam disposed in the non-display area and positioned near or outside the inclined surface of the encapsulation layer, a second dam disposed in the non-display area and positioned outside the first dam, and a surrounding organic pattern positioned between the first dam and the second dam.

The display device according to an aspect of the present disclosure may further include an outer power line disposed on the substrate in the non-display area and overlapping the first dam and the second dam.

The display device according to an aspect of the present disclosure may further include at least one insulating layer disposed between the surrounding organic pattern and the outer power line. The surrounding organic pattern overlaps the outer power line.

In the display device according to an aspect of the present disclosure, the outer power line may include a base voltage line for supplying a base voltage applied to the common electrode.

In the display device according to an aspect of the present disclosure, each of the first dam and the second dam may be a ring type disposed in the non-display area along an outer edge of the display area.

In the display device according to an aspect of the present disclosure, the surrounding organic pattern may be disposed on the non-display area along an outer edge of the display area, and the surrounding organic pattern may be a closed ring type organic layer and may completely surround the display area.

In the display device according to an aspect of the present disclosure, the surrounding organic pattern may be disposed on the non-display area along an outer edge of the display area, and the surrounding organic pattern may be an open ring type organic layer, and may be disconnected at a circuit connection area to which an integrated circuit is bonded or electrically connected.

According to the aspects of the present disclosure, a display device has a structure capable of blocking a film lifting phenomenon and a moisture permeation defect caused by static electricity in advance.

According to the aspects of the present disclosure, a display device is capable of blocking in advance a film lifting phenomenon and a moisture permeation defect under a narrow bezel structure.

According to the aspects of the present disclosure, a display device has a structure capable of preventing the outer power line from being affected by static electricity, thereby preventing film lifting and moisture permeation around the outer power line due to static electricity in advance.

According to the aspects of the present disclosure, a display device has a structure capable of increasing insulation between a touch routing line extending from or connected to the touch sensor metal and the outer power line.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a system configuration diagram of a display device according to an aspect of the present disclosure;

FIG. 2 is a plan view of a display panel according to an aspect of the present disclosure;

FIG. 3 shows a schematic structure of the display panel according to an aspect of the present disclosure;

FIG. 4 shows an example of a structure of a self-capacitance type touch sensor in the display device according to an aspect of the present disclosure;

FIG. 5 shows an example of a structure of a mutual-capacitance type touch sensor in the display device according to an aspect of the present disclosure;

FIG. 6 illustrates another example of a structure of a mutual capacitance type touch sensor in a display device according to an aspect of the present disclosure;

FIG. 7 illustrate cross-sectional structures in a non-display area of the display device according to an aspect of the present disclosure;

FIG. 8 illustrate cross-sectional structures in a non-display area of the display device according to an aspect of the present disclosure;

FIG. 9 illustrate cross-sectional structures in a non-display area of the display device according to an aspect of the present disclosure;

FIG. 10 show planar structures of a surrounding organic pattern of the display device according to an aspect of the present disclosure; and

FIG. 11 show planar structures of a surrounding organic pattern of the display device according to an aspect of the present disclosure.

### DETAILED DESCRIPTION

In the following description of examples or aspects of the present disclosure, reference will be made to the accompanying drawings in which it is shown by way of illustration specific examples or aspects that can be implemented, and in which the same reference numerals and signs can be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various aspects of the present disclosure will be described in detail with reference to the accompanying drawings.

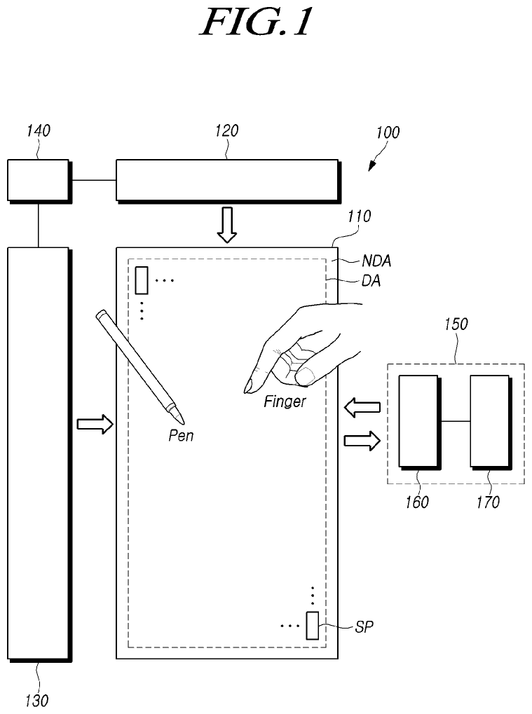

FIG. 1 is a system configuration diagram of a display device 100 according to aspects of the present disclosure.

Referring to FIG. 1, the display device 100 may include a display panel 110 and a display driving circuit for driving the display panel 110, as components for displaying an image.

The display driving circuit may include a data driving circuit 120, a gate driving circuit 130, and a display controller 140, and the like.

The display panel 110 may include a display area DA in which an image is displayed and a non-display area NDA in which an image is not displayed. The non-display area NDA may be an area outside the display area DA, and may also be referred to as a bezel area. All or part of the non-display area NDA may be an area visible from the front side of the display device 100, or an area that is bent and not visible from the front side of the display device 100.

The display panel 110 may include a plurality of sub-pixels SP. Also, the display panel 110 may further include various types of signal lines to drive the plurality of sub-pixels SP.

The display device 100 according to an aspect of the present disclosure may be a liquid crystal display device or the like, or a self-luminous display device in which the display panel 110 emits light by itself. When the display device 100 according to aspects of the present disclosure is the self-luminous display device, each of the plurality of sub-pixels SP may include a light emitting device.

For example, the display device 100 according to aspects of the present disclosure may be an organic light emitting display device in which a light emitting device is implemented as an organic light emitting diode OLED. For another example, the display device 100 according to aspects of the present disclosure may be an inorganic light emitting display device in which a light emitting device is implemented as an inorganic material-based light emitting diode. As another example, the display device 100 according to aspects of the present disclosure may be a quantum dot display device in which a light emitting device is implemented with quantum dots, which are semiconductor crystals that emit light by themselves.

The structure of each of the plurality of sub-pixels SP may vary according to the type of the display device 100. For example, when the display device 100 is a self-luminous display device in which the sub-pixel SP emits light by itself, each sub-pixel SP may include a light emitting device emitting light by itself, one or more transistors, and one or more capacitors.

For example, various types of signal lines may include a plurality of data lines transmitting data signals (also called data voltages or image signals) and a plurality of gate lines transmitting gate signals (also called scan signals), and the like.

The plurality of data lines and the plurality of gate lines may cross each other. Each of the plurality of data lines may be disposed while extending in the first direction. Each of the plurality of gate lines may be disposed while extending in the second direction.

Here, the first direction may be a column direction and the second direction may be a row direction. Alternatively, the first direction may be a row direction and the second direction may be a column direction.

The data driving circuit 120 is a circuit for driving the plurality of data lines, and may output data signals to the plurality of data lines. The gate driving circuit 130 is a circuit for driving the plurality of gate lines, and may output gate signals to the plurality of gate lines. The display controller 140 is a device for controlling the data driving circuit 120 and the gate driving circuit 130, and may control driving timings for the plurality of data lines and driving timings for the plurality of gate lines.

The display controller 140 may supply a data driving control signal to the data driving circuit 120 to control the data driving circuit 120, and may supply a gate driving control signal to the gate driving circuit 130 to control the gate driving circuit 130.

The data driving circuit 120 may supply data signals to the plurality of data lines according to the driving timing control of the display controller 140. The data driving circuit 120 may receive digital image data from the display controller 140, convert the received digital image data into data signals corresponding to an analog voltage, and output the converted data signals to a plurality of data lines.

The gate driving circuit 130 may supply gate signals to the plurality of gate lines GL according to the timing control of the display controller 140. The gate driving circuit 130 may receive various gate driving control signals (e.g., start signal, reset signal, etc.), a first gate voltage corresponding to a turn-on level voltage, and a second gate voltage corresponding to a turn-off level voltage. The gate driving circuit 130 may generate gate signals based on the various gate driving control signals, the first gate voltage, and the second gate voltage, and may supply the generated gate signals to the plurality of gate lines.

For example, the data driving circuit 120 may be connected to the display panel 110 in a tape automated bonding (TAB) method, a chip-on-glass (COG) method, or a chip-on-panel (COP) method. Alternatively, the data driving circuit 120 may be implemented in a chip-on-film (COF) method and connected to the display panel 110.

The gate driving circuit 130 may be connected to the display panel 110 by a tape automated bonding (TAB) method, a chip-on-glass (COG) method, or a chip-on-film (COF) method. Alternatively, the gate driving circuit 130 may be formed in the non-display area NDA of the display panel 110 in a gate in panel (GIP) type. The gate driving circuit 130 may be disposed on or connected to the substrate. That is, in the case of the GIP type, the gate driving circuit 130 may be disposed in the non-display area NDA of the substrate. The gate driving circuit 130 may be connected to the substrate in the case of a chip-on-glass (COG) type, a chip-on-film (COF) type, or the like.

Meanwhile, at least one of the data driving circuit 120 and the gate driving circuit 130 may be disposed in the display area DA. For example, at least one of the data driving circuit 120 and the gate driving circuit 130 may be disposed to partially or entirely overlap the sub-pixels SP.

The data driving circuit 120 may be connected to one side (e.g., top or bottom) of the display panel 110. Depending on the driving method, the panel design method, etc., the data driving circuit 120 may be connected to both sides (e.g., top and bottom) of the display panel 110, or may be connected to two or more of the four sides of the display panel 110.

The gate driving circuit 130 may be connected to one side (e.g., left or right) of the display panel 110. Depending on the driving method, the panel design method, etc., the gate driving circuit 130 may be connected to both sides (e.g., left and right) of the display panel 110, or may be connected to two or more of the four sides of the display panel 110.

The display controller 140 may be implemented as a separate component from the data driving circuit 120. Alternatively, the display controller 140 may be integrated with the data driving circuit 120 to be implemented as an integrated circuit.

The display controller 140 may be a timing controller used in a conventional display technology, or a control device capable of further performing other control functions including a timing controller. The display controller 140 may be implemented with various circuits or electronic components such as an integrated circuit (IC), a field programmable gate array (FPGA), an application specific integrated circuit (ASIC), or a processor.

The display controller 140 may be mounted on a printed circuit board or a flexible printed circuit, and may be electrically connected to the data driving circuit 120 and the gate driving circuit 130 through a printed circuit board or a flexible printed circuit.

The display controller 140 may transmit and receive signals to and from the data driving circuit 120 according to one or more predetermined interfaces. Here, for example, the interfaces may include at least one of a Low Voltage Differential Signaling (LVDS) interface, an Embedded Clock Point-to-Point Interface (EPI), and a Serial Peripheral Interface (SPI).

The display device 100 according to aspects of the present disclosure may further provide a touch sensing function as well as an image display function. In order to provide a touch sensing function, the display device 100 according to aspects of the present disclosure may include a touch panel and a touch sensing circuit 150. The touch sensing circuit 150 may sense the touch panel to detect whether a touch is generated by a touch object such as a finger or a pen, or detect a touch position.

The touch sensing circuit 150 may include a touch driving circuit 160 configured to drive and sense the touch panel to generate and output touch sensing data, and a touch controller 170 configured to detect a touch occurrence or detect a touch position using touch sensing data.

The touch panel may include a plurality of touch electrodes as a touch sensor. The touch panel may further include a plurality of touch routing lines for electrically connecting the plurality of touch electrodes and the touch driving circuit 160. A touch panel or touch electrode is also called a touch sensor.

The touch panel may exist outside the display panel 110 or inside the display panel 110. When the touch panel is external to the display panel 110, the touch panel is referred to as an external type. When the touch panel is an external type, the touch panel and the display panel 110 may be separately manufactured and combined during an assembly process. The external touch panel may include a substrate and a plurality of touch electrodes on the substrate. When the touch panel is present inside the display panel 110, the touch panel is referred to as a built-in type. When the touch panel is a built-in type, the touch panel may be formed in the display panel 110 during a manufacturing process of the display panel 110.

The touch driving circuit 160 may supply a touch driving signal to at least one of the plurality of touch electrodes and sense at least one of the plurality of touch electrodes to generate touch sensing data.

The touch sensing circuit 150 may perform touch sensing using a self-capacitance sensing method or a mutual-capacitance sensing method.

When the touch sensing circuit 150 performs touch sensing using a self-capacitance sensing method, the touch sensing circuit 150 may perform touch sensing based on capacitance between each touch electrode and a touch object (e.g., a finger, a pen, etc.).

According to the self-capacitance sensing method, each of the plurality of touch electrodes may serve as both a driving touch electrode and a sensing touch electrode. The touch driving circuit 160 may drive all or part of the plurality of touch electrodes and sense all or part of the plurality of touch electrodes.

When the touch sensing circuit 150 performs touch sensing using a mutual-capacitance sensing method, the touch sensing circuit 150 may perform touch sensing based on capacitances between touch electrodes.

According to the mutual-capacitance sensing method, the plurality of touch electrodes may be divided into driving touch electrodes and sensing touch electrodes. The touch driving circuit 160 may drive the driving touch electrodes and sense the sensing touch electrodes.

The touch driving circuit 160 and the touch controller 170 included in the touch sensing circuit 150 may be implemented as separate devices or may be integrated into one device.

Also, the touch driving circuit 160 and the data driving circuit 120 may be implemented as separate devices or may be integrated and implemented as one device.

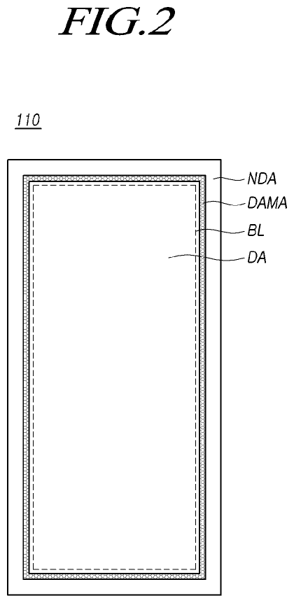

FIG. 2 is a plan view of the display panel 110 according to aspects of the present disclosure.

Referring to FIG. 2, the display panel 110 may include a display area DA on which an image is displayed and a non-display area NDA that is an outer area of an outer boundary line BL of the display area DA.

In the display area DA of the display panel 110, a plurality of sub-pixels SP for displaying an image may be arranged, and various electrodes or signal lines for driving the display may be arranged.

In the display area DA of the display panel 110, a touch sensor for sensing a touch may be disposed, and a plurality of touch routing lines electrically connected to the touch sensor may be disposed. Accordingly, the display area DA may also be referred to as a touch sensing area in which touch sensing is possible.

Link lines may be disposed in the non-display area NDA of the display panel 110. The link lines may be extended portions of various signal lines disposed in the display area DA or lines electrically connected to various signal lines disposed in the display area DA.

Also, display pads electrically connected to link lines may be disposed in the non-display area NDA of the display panel 110. The display pads disposed in the non-display area NDA may be bonded to or electrically connected to the display driving circuits 120 and 130. For example, the display pads disposed in the non-display area NDA may include data pads to which data link lines are connected. The data link lines may be extended portions of the data lines or lines connected to the data lines.

In the non-display area NDA of the display panel 110, touch routing lines electrically connected to the touch sensor disposed in the display area DA may be disposed, and touch pads electrically connected to the touch routing lines may be disposed. The touch pads disposed in the non-display area NDA may be bonded to or electrically connected to the touch driving circuit 160.

Some of the touch electrodes among the plurality of touch electrodes disposed in the display area DA may be disposed in the non-display area NDA, or a portion of the outermost touch electrode among the plurality of touch electrodes disposed in the display area DA may extend to the non-display area NDA. One or more electrodes (touch electrodes) made of the same material as the plurality of touch electrodes disposed in the display area DA may be further disposed in the non-display area NDA.

All touch sensors may be present in the display area DA. Alternatively, most of the touch sensors are present in the display area DA, and a portion of the touch sensor may exist in the non-display area NDA or may exist across the display area DA and the non-display area NDA.

Meanwhile, referring to FIG. 2, the display panel 110 of the display device 100 according to aspects of the present disclosure may include a dam area DAMA in which at least one dam is disposed to prevent the easily collapsing layer in the display panel 110 from collapsing. For example, the easily collapsing layer in the display panel 110 may include an encapsulation layer.

The dam area DAMA may exist at or near a boundary point between the display area DA and the non-display area NDA. For example, the dam area DAMA may be an area whose height suddenly increases while horizontally moving inward from the outermost part of the panel toward the display area DA.

The dam area DAMA may refer to a region in which the slope of the encapsulation layer suddenly softens or rises again while descending along the slope of the encapsulation layer.

At least one dam disposed in the dam area DAMA may be disposed to surround the display area DA in all directions (e.g., 4 directions), or may be disposed to surround the display area DA only in one to three directions (e.g., in the direction with a layer that is prone to collapsing) among all directions (e.g., 4 directions).

At least one dam disposed in the dam area DAMA may be a single pattern that is all connected or may include two or more disconnected patterns.

When two or more dams are placed in a dam area DAMA, a dam closest to the display area DA may be referred to as a primary dam, and a dam that is second closest to the display area DA may be referred to as a secondary dam. In the dam area DAMA, there may be only a primary dam in one direction, and both a primary dam and a secondary dam may be present in the other direction.

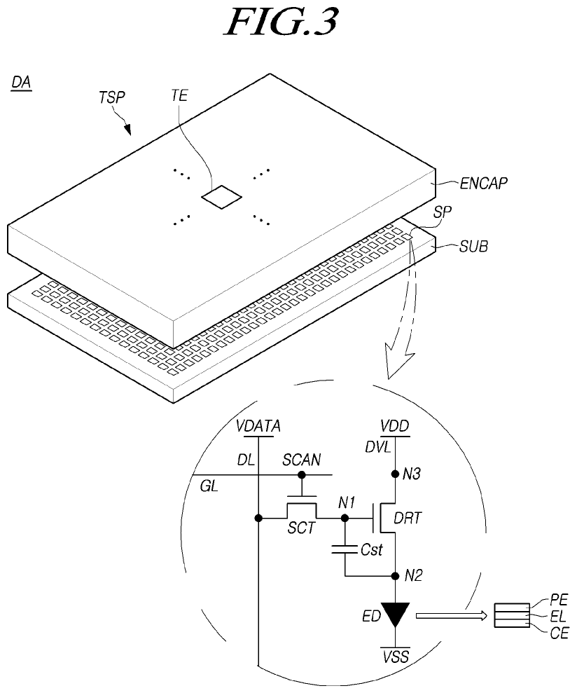

FIG. 3 shows a schematic structure of the display panel 110 according to aspects of the present disclosure.

Referring to FIG. 3, the display panel 110 according to aspects of the present disclosure may have a built-in touch panel TSP. That is, in the display device 100, the touch panel TSP may be a built-in type embedded in the display panel 110. The built-in touch panel TSP is also referred to as an in-cell type or on-cell type touch panel TSP.

Each sub-pixel SP in the display area DA of the display panel 110 may include a light emitting device ED, a driving transistor DRT for driving the light emitting device ED, a scan transistor SCT for transferring the data voltage VDATA to a first node N1 of the driving transistor DRT, and a storage capacitor Cst for maintaining a constant voltage for one frame.

The driving transistor DRT may include a first node N1 to which a data voltage can be applied, a second node N2 electrically connected to the light emitting device ED, and a third node N3 to which the driving voltage VDD is applied from a driving voltage line DVL. The first node N1 may be a gate node, the second node N2 may be a source node or a drain node, and the third node N3 may be a drain node or a source node.

The light emitting device ED may include a pixel electrode PE, an emission layer EL, and a common electrode CE. The pixel electrode PE may be disposed in each sub-pixel SP and may be electrically connected to the second node N2 of the driving transistor DRT of each sub-pixel SP. The common electrode CE is disposed in common to the plurality of sub-pixels SP, and a base voltage VSS may be applied thereto. For example, the light emitting device ED may be an organic light emitting diode (OLED), an inorganic light emitting diode, or a quantum dot light emitting device. In this case, when the light emitting device ED is an organic light emitting diode (OLED), the light emitting layer EL of the light emitting device ED may include an organic light emitting layer including an organic material.

The scan transistor SCT may be turned on or turned off by the scan signal SCAN, which is a gate signal applied through the gate line GL. The scan transistor SCT may control the connection between the first node N1 of the driving transistor DRT and the data line DL.

The storage capacitor Cst may be electrically connected between the first node N1 and the second node N2 of the driving transistor DRT.

Each sub-pixel SP may have a 2T (Transistor) 1C (Capacitor) structure including two transistors (DRT, SCT) and one capacitor (Cst) as shown in FIG. 3. In some cases, each sub-pixel SP may further include one or more transistors or may further include one or more capacitors.

The storage capacitor Cst is not a parasitic capacitor (e.g., Cgs, Cgd) that is an internal capacitor that may exist between the first node N1 and the second node N2 of the driving transistor DRT, but an external capacitor intentionally designed outside the driving transistor DRT.

Each of the driving transistor DRT and the scan transistor SCT may be an n-type transistor or a p-type transistor.

Since the circuit elements (especially, the light emitting device ED) in each sub-pixel SP are vulnerable to external moisture or oxygen, an encapsulation layer ENCAP for preventing external moisture or oxygen from penetrating into the circuit elements (especially, the light emitting device ED) may be disposed in the display panel 110.

Meanwhile, in the display device 100, the touch panel TSP may be formed on the encapsulation layer ENCAP. That is, in the display device 100, the touch sensor included in the touch panel TSP may be disposed on the encapsulation layer ENCAP. The touch sensor may include a plurality of touch electrodes TE.

As described above, the encapsulation layer ENCAP may be disposed between the touch electrodes TE and the common electrode CE. Under this structure, when a touch driving signal or a touch sensing signal is applied to at least one of the plurality of touch electrodes TE included in the touch sensor during touch sensing, a potential difference may be formed between the touch electrodes TE and the common electrode CE. Due to this potential difference, unnecessary parasitic capacitance may be formed between the touch electrodes TE and the common electrode CE. Parasitic capacitance can degrade touch sensitivity.

In order to reduce the parasitic capacitance, the distance between the touch electrodes TE and the common electrode CE may be designed to be greater than or equal to a certain value (e.g., 5 μm) in consideration of the panel thickness, the panel manufacturing process, and display performance. For example, the thickness of the encapsulation layer ENCAP may be designed to be at least 5 μm or more.

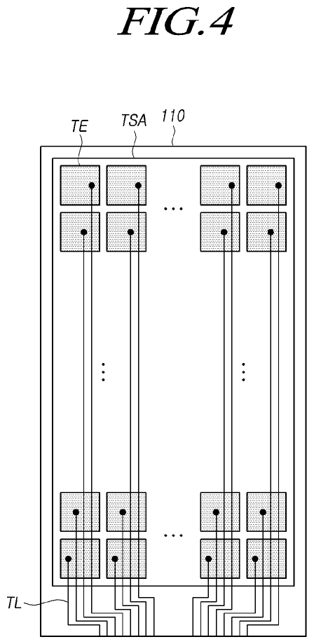

FIG. 4 shows an example of a structure of a self-capacitance type touch sensor in the display device 100 according to aspects of the present disclosure.

Referring to FIG. 4, the display device 100 according to aspects of the present disclosure may include a touch sensor in the touch sensing area TSA of the display panel 110. The touch sensor may include a plurality of touch electrodes TE.

Referring to FIG. 4, the display device 100 according to aspects of the present disclosure may include a self-capacitance type touch sensor to sense a touch based on self-capacitance.

Referring to FIG. 4, the self-capacitance type touch sensor may include a plurality of touch electrodes TE disposed to be separated from each other in the touch sensing area TSA.

Referring to FIG. 4, the self-capacitance type touch sensor may further include a plurality of touch routing lines TL for electrically connecting each of the plurality of touch electrodes TE to the touch driving circuit 160.

Referring to FIG. 4, in the self-capacitance type touch sensor, each of the plurality of touch electrodes TE may not cross each other. Also, the plurality of touch electrodes TE may not be electrically connected in the display panel 110. In a self-capacitance type touch sensor, each of the plurality of touch electrodes TE may be one touch node corresponding to a touch coordinate.

Referring to FIG. 4, when sensing touch based on self-capacitance, the touch driving circuit 160 may supply a touch driving signal to at least one of the plurality of touch electrodes TE and sense the touch electrode TE to which the touch driving signal is supplied.

The sensed value of the touch electrode TE to which the touch driving signal is supplied may be a value corresponding to a capacitance or a capacitance change in the touch electrode TE to which the touch driving signal is supplied. The capacitance in the touch electrode TE to which the touch driving signal is supplied may be a capacitance between the touch electrode TE to which the touch driving signal is supplied and a touch object such as a finger.

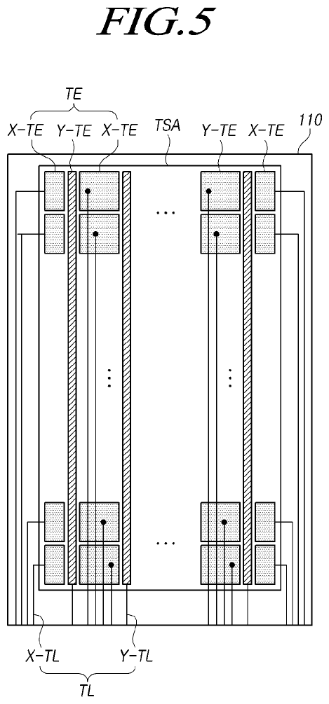

FIG. 5 shows an example of a structure of a mutual-capacitance type touch sensor in the display device 100 according to aspects of the present disclosure.

Referring to FIG. 5, the mutual-capacitance type touch sensor may include a plurality of first touch electrode lines and a plurality of second touch electrode lines.

Referring to FIG. 5, each of the plurality of first touch electrode lines may include a plurality of first touch electrodes X-TE disposed in the same row and electrically connected to each other. Each of the plurality of second touch electrode lines may be one second touch electrode Y-TE disposed in one column.

Alternatively, each of the plurality of first touch electrode lines may be one first touch electrode X-TE disposed in one row. Each of the plurality of second touch electrode lines may include a plurality of second touch electrodes Y-TE disposed in the same column and electrically connected to each other.

The plurality of first touch electrodes X-TE included in each of the plurality of first touch electrode lines may be electrically connected in the display panel 110.

In a different manner, the first touch electrodes X-TE included in each of the plurality of first touch electrode lines are electrically separated in the display panel 110, but may be electrically connected in the touch driving circuit 160.

Each of the plurality of first touch electrode lines may be disposed in different rows and may be electrically separated from each other. Each of the plurality of second touch electrode lines may be disposed in different columns and may be electrically separated from each other.

In view of the equivalent circuit structure, the plurality of first touch electrode lines and the plurality of second touch electrode lines may electrically cross each other. Accordingly, the plurality of first touch electrode lines and the plurality of second touch electrode lines may correspond to each other to form capacitances (mutual-capacitances).

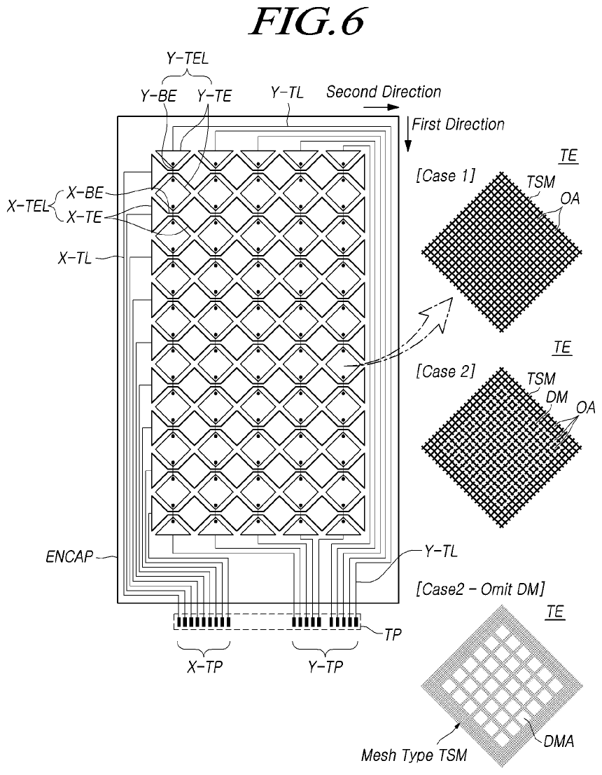

Referring to FIG. 5 and FIG. 6, the mutual-capacitance type touch sensor may further include a plurality of touch routing lines TL (X-TL, Y-TL) for electrically connecting each of the plurality of touch electrodes TE (X-TE, Y-TE) to the touch driving circuit 160.

Referring to FIG. 5, in the mutual-capacitance type touch sensor, points where the plurality of first touch electrode lines and the plurality of second touch electrode lines intersect may be touch nodes corresponding to touch coordinates.

Referring to FIG. 5, when sensing a touch based on mutual-capacitance, the touch driving circuit 160 may supply a touch driving signal to at least one of the plurality of first touch electrode lines and sense at least one of the plurality of second touch electrode lines.

In this case, the plurality of first touch electrode lines may be driving touch electrode lines (also referred to as transmission touch electrode lines), and the plurality of second touch electrode lines may be sensing touch electrode lines (also referred to as reception touch electrode lines).

The sensed value sensed by the touch driving circuit 160 through each second touch electrode line may be a value corresponding to a capacitance or a capacitance change between the first touch electrode line and the second touch electrode line.

Alternatively, when sensing a touch based on the mutual-capacitance, the touch driving circuit 160 may supply a touch driving signal to at least one of the plurality of second touch electrode lines and sense at least one of the plurality of first touch electrode lines.

In this case, the plurality of second touch electrode lines may be driving touch electrode lines (also referred to as transmission touch electrode lines), and the plurality of first touch electrode lines may be sensing touch electrode lines (also referred to as reception touch electrode lines).

The sensed value sensed by the touch driving circuit 160 through each first touch electrode line may be a value corresponding to a capacitance or a capacitance change between the first touch electrode line and the second touch electrode line.

FIG. 6 illustrates another example of a structure of a mutual capacitance type touch sensor in the display device 100 according to aspects of the present disclosure.

Referring to FIG. 6, when the display device 100 performs touch sensing based on mutual capacitance, the touch sensor structure of the display device 100 may include a plurality of first touch electrode lines X-TEL and a plurality of second touch electrode lines Y-TEL. Here, the plurality of first touch electrode lines X-TEL and the plurality of second touch electrode lines Y-TEL may be positioned on the encapsulation layer ENCAP.

The plurality of first touch electrode lines X-TEL and the plurality of second touch electrode lines Y-TEL may cross each other. Each of the plurality of second touch electrode lines Y-TEL may be disposed in a first direction (e.g., a column direction). Each of the plurality of first touch electrode lines X-TEL may be disposed in a second direction (e.g., a row direction) different from the first direction.

In this specification, the first direction and the second direction may be relatively different from each other. For example, the first direction may be a y-axis direction (column direction), and the second direction may be an x-axis direction (row direction). Conversely, the first direction may be an x-axis direction (row direction) and the second direction may be a y-axis direction (column direction). In addition, the first direction and the second direction may be orthogonal to each other, but may not be orthogonal to each other.

In addition, in this specification, rows and columns are relative, and the rows and columns may be changed according to a viewing point of view. Also, the first direction may be a direction parallel to a direction in which the data line DL is disposed, and the second direction may be a direction parallel to a direction in which the gate line GL is disposed.

According to the example of the touch sensor structure of FIG. 6, each of the plurality of first touch electrode lines X-TEL may include a plurality of first touch electrodes X-TE electrically connected to each other, and each of the plurality of second touch electrode lines Y-TEL may include a plurality of second touch electrodes Y-TE electrically connected to each other.

The roles of the plurality of first touch electrode lines X-TEL and the roles of the plurality of second touch electrode lines Y-TEL may be different from each other.

The plurality of first touch electrode lines X-TEL may be driving touch electrode lines driven as a touch driving signal is applied by the touch driving circuit 160, and the plurality of second touch electrode lines Y-TEL may be sensing touch electrode lines sensed by the touch driving circuit 160.

In this case, the plurality of first touch electrodes X-TE included in each of the plurality of first touch electrode lines X-TEL may be driving touch electrodes, and the plurality of second touch electrodes Y-TE included in each of the plurality of second touch electrode lines Y-TEL may be sensing touch electrodes.

The plurality of first touch electrode lines X-TEL may be sensing touch electrode lines sensed by the touch driving circuit 160, and the plurality of second touch electrode lines Y-TEL may be driving touch electrode lines driven as a touch driving signal is applied by the touch driving circuit 160.

In this case, the plurality of first touch electrodes X-TE included in each of the plurality of first touch electrode lines X-TEL may be sensing touch electrodes, and the plurality of second touch electrodes Y-TE included in each of the plurality of second touch electrode lines Y-TEL may be driving touch electrodes.

The touch sensor may include the plurality of first touch electrode lines X-TEL and the plurality of second touch electrode lines Y-TEL, and may further include a plurality of touch routing lines X-TL and Y-TL.

A plurality of touch routing lines X-TL and Y-TL may include one or more first touch routing lines X-TL connected to each of the plurality of first touch electrode lines X-TEL, and one or more second touch routing lines Y-TL connected to each of the plurality of second touch electrode lines Y-TEL.

Referring to FIG. 6, each of the plurality of first touch electrode lines X-TEL may include a plurality of first touch electrodes X-TE disposed in the same row (or column) and electrically connected, and at least one first touch bridge electrode X-BE electrically connecting first touch electrodes X-TE adjacent to each other in the second direction.

As shown in FIG. 6, the first touch bridge electrode X-BE may connect two adjacent touch electrodes X-TE. The first touch bridge electrode X-BE may be a metal integrated with two adjacent touch electrodes X-TE. As a different structure, the first touch bridge electrode X-BE may be positioned on a different layer from the two adjacent first touch electrodes X-TE and may be electrically connected to the two adjacent first touch electrodes X-TE through a contact hole.

Referring to FIG. 6, each of the plurality of second touch electrode lines Y-TEL may include a plurality of second touch electrodes Y-TE disposed in the same column (or row) and electrically connected, and at least one second touch bridge electrode Y-BE electrically connecting two second touch electrodes Y-TE adjacent to each other in a first direction.

As shown in FIG. 6, the second touch bridge electrode Y-BE may connect two adjacent touch electrodes Y-TE. The second touch bridge electrode Y-BE may be positioned on a different layer from the two adjacent second touch electrodes Y-TE and may be electrically connected to the two adjacent second touch electrodes Y-TE through a contact hole. As a different structure, the second touch bridge electrode Y-BE may be a metal integrated with two adjacent touch electrodes Y-TE.

In an intersection area where the first touch electrode line X-TEL and the second touch electrode line Y-TEL intersect, the first touch bridge electrode X-BE and the second touch bridge electrode Y-BE may cross each other.

Accordingly, in order to be disposed such that the plurality of first touch electrode lines X-TEL and the plurality of second touch electrode lines Y-TEL cross each other, the plurality of first touch electrodes X-TE, the plurality of first touch bridge electrodes X-BE, the plurality of second touch electrodes Y-TE, and the plurality of second touch bridge electrodes Y-BE may be positioned in two or more layers.

Referring to FIG. 6, each of the plurality of first touch electrode lines X-TEL may be electrically connected to a corresponding first touch pad X-TP in a touch pad unit TP through one or more first touch routing lines X-TL. Each of the plurality of second touch electrode lines Y-TEL may be electrically connected to a corresponding second touch pad Y-TP in the touch pad unit TP through one or more second touch routing lines Y-TL.

A touch sensor may include a plurality of first touch electrodes X-TE included in each of the plurality of first touch electrode lines X-TEL, and a plurality of second touch electrodes Y-TE included in each of the plurality of second touch electrode lines Y-TEL. The touch sensor may further include a plurality of first touch bridge electrodes X-BE and a plurality of second touch bridge electrodes Y-BE. The touch sensor may further include a plurality of first touch routing lines X-TL and a plurality of second touch routing lines Y-TL.

Some of the components constituting the touch sensor may include a touch sensor metal TSM. The touch sensor metal TSM may be a metal disposed on a single layer. Alternatively, the touch sensor metal TSM may include a first touch sensor metal TSM and a second touch sensor metal TSM disposed on different layers. The first touch sensor metal TSM and the second touch sensor metal TSM may be separated by an insulating layer (also referred as touch-Interlayer insulating layer). One of the first touch sensor metal TSM and the second touch sensor metal TSM may also be referred to as a touch bridge metal. Below, the layer in which the first touch sensor metal TSM is located may be referred to as a first touch sensor metal layer, and a layer in which the second touch sensor metal TSM is located may be referred to as a second touch sensor metal layer. One of the first touch sensor metal layer and the second touch sensor metal layer may be referred to as a touch bridge metal layer. A touch-interlayer insulating layer may be disposed between the first touch sensor metal layer and the second touch sensor metal layer. For example, the first touch sensor metal layer may be a layer higher than the second touch sensor metal, and the second touch sensor metal layer may be a touch bridge metal layer.

For example, the plurality of first touch electrodes X-TE included in each of the plurality of first touch electrode lines X-TEL and the plurality of second touch electrodes Y-TE included in each of the plurality of second touch electrode lines Y-TEL may include a first touch sensor metal TSM. That is, the plurality of first touch electrodes X-TE and the plurality of second touch electrodes Y-TE may be located in the first touch sensor metal layer.

For example, among the plurality of first touch bridge electrodes X-BE and the plurality of second touch bridge electrodes Y-BE, one (e.g., first touch bridge electrodes X-BE) may include the first touch sensor metal TSM, and the other one (e.g., second touch bridge electrodes Y-BE) may include the second touch sensor metal TSM. Here, the second touch sensor metal TSM may be referred to as a touch bridge metal. That is, one of the plurality of first touch bridge electrodes X-BE and the plurality of second touch bridge electrodes Y-BE may be located in the first touch sensor metal layer, and the other one may be located in the touch bridge metal layer that is the second touch sensor metal layer.

For example, both of the plurality of first touch routing lines X-TL and the plurality of second touch routing lines Y-TL may include the first touch sensor metal TSM. Alternatively, both of the plurality of first touch routing lines X-TL and the plurality of second touch routing lines Y-TL may include the second touch sensor metal TSM that is a touch bridge metal. Alternatively, among the plurality of first touch routing lines X-TL and the plurality of second touch routing lines Y-TL, one may include a first touch sensor metal TSM, and the other one may include a second touch sensor metal TSM that is a touch bridge metal. That is, the plurality of first touch routing lines X-TL and the plurality of second touch routing lines Y-TL may be located in at least one of the first touch sensor metal layer and the second touch sensor metal layer (touch bridge metal layer).

As shown in FIG. 6, the plurality of first touch electrodes X-TE and the plurality of first touch bridge electrodes X-BE included in the plurality of first touch electrode lines X-TEL may be disposed on the encapsulation layer ENCAP. The plurality of second touch electrodes Y-TE and the plurality of second touch bridge electrodes Y-BE included in the plurality of second touch electrode lines Y-TEL may be disposed on the encapsulation layer ENCAP. The encapsulation layer ENCAP may be disposed on the common electrode CE.

As shown in FIG. 6, the plurality of first touch routing lines X-TL may electrically connect the plurality of first touch electrode lines X-TEL and the plurality of first touch pads X-TP. The plurality of second touch routing lines Y-TL may electrically connect the plurality of second touch electrode lines Y-TEL and the plurality of second touch pads Y-TP. Each of the plurality of first touch routing lines X-TL may be disposed on the encapsulation layer ENCAP and may extend to a place without the encapsulation layer ENCAP to be electrically connected to the plurality of first touch pads X-TP. Each of the plurality of second touch routing lines Y-TL may be disposed on the encapsulation layer ENCAP and may extend to a place without the encapsulation layer ENCAP to be electrically connected to the plurality of second touch pads Y-TP. The encapsulation layer ENCAP may be located in the display area DA and, in some cases, may extend to the non-display area NDA.

In the display panel 110 of the display device 100, each touch electrode TE (X-TE, Y-TE) may be a plate-shaped touch sensor metal TSM without an opening. In this case, for example, each touch electrode TE may be a transparent electrode. A transparent electrode is also called a transmissive electrode. The touch electrode TE may be made of a transparent electrode material so that light emitted from the light emitting devices ED under the encapsulation layer ENCAP may pass through the touch electrode TE on the encapsulation layer ENCAP.

Alternatively, as shown in FIG. 6, each touch electrode TE disposed in the display panel 110 may be of a mesh type like Case 1. In case 1, each touch electrode TE may be formed of a touch sensor metal TSM that is patterned in a mesh type and formed with a plurality of openings OA. The touch sensor metal TSM of each touch electrode TE may be a portion substantially corresponding to the touch electrode TE, and may be a portion to which a touch driving signal is applied or a portion to which a touch sensing signal is sensed. The touch sensor metal TSM of each touch electrode TE may be positioned on a bank disposed in an area other than the emission areas of the sub-pixels SP.

As shown in FIG. 6, as in Case 2, when each touch electrode TE include a touch sensor metal TSM patterned in a mesh type, a plurality of openings OA formed in the touch sensor metal TSM may exist in the area of the touch electrode TE. Each of the plurality of openings OA formed in the touch sensor metal TSM may correspond to a light emitting area of one or more sub-pixels SP or may correspond to a transmissive area of the display panel 110. The plurality of openings OA formed in the touch sensor metal TSM of the touch electrode TE may serve as a path through which light is transmitted so that light emitted from the light emitting devices ED under the encapsulation layer ENCAP can pass through the area of the touch electrode TE on the encapsulation layer ENCAP. Accordingly, the luminous efficiency of the light emitting area of each sub-pixel SP may be increased. Alternatively, when the display device 100 is a transparent display, the plurality of openings OA formed in the touch sensor metal TSM of the touch electrode TE may be a path through which light passes through the area of the touch electrode TE so that light between the front and back surfaces of the display panel 110 may pass through. Accordingly, light transmittance of the transmission region of the display panel 110 may be increased.

For example, the outline shape of the touch electrode TE may be a quadrangle such as a diamond shape or a rhombus, or various shapes such as a triangle, a pentagon, or a hexagon. Each of the plurality of openings OA may have various shapes according to the shape of the touch electrode TE or the mesh shape of the touch sensor metal TSM.

Referring to FIG. 6, as in case 2, in the area of each touch electrode TE, one or more dummy metals DM that are disconnected from the mesh-type touch sensor metal TSM may exist. The dummy metal DM may be positioned within the area of the touch electrode TE while being surrounded by the touch sensor metal TSM. Unlike the touch sensor metal TSM, the dummy metal DM is a portion to which a touch driving signal is not applied and a touch sensing signal is not sensed, and may be an electrically floating metal. The touch sensor metal TSM may be electrically connected to the touch driving circuit 160, but the dummy metal DM may not be electrically connected to the touch driving circuit 160.

In each area of all the touch electrodes TE, one or more dummy metals DM may exist in a state in which they are disconnected (separated) from the touch sensor metal TSM. Alternatively, only in the area of the touch electrodes TE included in the first group among all the touch electrodes TE, one or more dummy metals DM exist in a state in which they are disconnected from the touch sensor metal TSM. And the dummy metal DM may not exist in the area of the touch electrodes TE included in the second group among all the touch electrodes TE.

Meanwhile, in relation to the role of the dummy metal DM, when one or more dummy metals DM do not exist in the area of the touch electrode TE and only the touch sensor metal TSM exists in a mesh type, a visibility issue in which the outline of the touch sensor metal TSM is visible on the screen may occur. In contrast, as shown in FIG. 6, when one or more dummy metals DM are present in the area of the touch electrode TE, a visibility issue in which the outline of the touch sensor metal TSM is visible on the screen may be prevented.

In addition, by adjusting the presence, number, or ratio of the dummy metal DM for each touch electrode TE, the capacitance may be adjusted for each touch electrode TE to improve touch sensitivity. Here, the ratio of the dummy metal DM in each touch electrode TE may be the ratio of the area occupied by the dummy metal DM in the area of the touch electrode TE. Alternatively, the ratio of the dummy metal DM in each touch electrode TE may be the ratio of the area of the touch sensor metal TSM to the area of the dummy metal DM.

Meanwhile, by cutting (or etching) some points in the touch sensor metal TSM formed in the area of one touch electrode TE, the cut touch sensor metal TSM may be formed of the dummy metal DM. That is, the touch sensor metal TSM and the dummy metal DM may be formed of the same material on the same layer.

Referring to FIG. 6, in Case 2, when the plurality of dummy metals DM present in the region of one touch electrode TE are omitted and only the touch sensor metal TSM is illustrated, a plurality of dummy areas DMA may exist in the area where the touch sensor metal TSM is disposed. The plurality of dummy areas DMA correspond to the plurality of dummy metals DM.

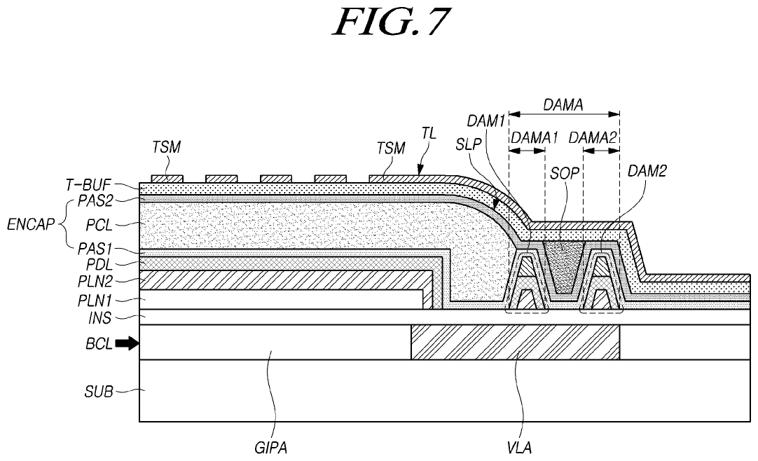

FIGS. 7 to 9 illustrate cross-sectional structures in the non-display area NDA of the display device 100 according to aspects of the present disclosure.

Referring to FIGS. 7 to 9, the display panel 110 of the display device 100 according to aspects of the present disclosure may include a substrate SUB including a display area DA and a non-display area NDA positioned outside the display area DA, a common electrode CE disposed on the substrate SUB, and an encapsulation layer ENCAP disposed on the common electrode CE.

Hereinafter, the stacked structure (also called laminate structure) of the display panel 110 in the non-display area NDA will be described in more detail.

The substrate SUB may have a single-layer structure including a glass substrate or a plastic substrate, or a multi-layer structure including one or more PI (Polyimide) substrates and one or more buffer layers.

One or more insulating layers INS may be disposed on the substrate SUB, and a first planarization layer PLN1 and a second planarization layer PLN2 may be disposed on the one or more insulating layers INS.

A pixel defining layer PDL may be disposed on the first planarization layer PLN1 and the second planarization layer PLN2. The pixel defining layer PDL may include a bank or a spacer.

An encapsulation layer ENCAP may be disposed on the pixel defining layer PDL.

In the display area DA, transistors DRT and SCT may be disposed under the first planarization layer PLN1, and the light emitting device ED may be disposed between the second planarization layer PLN2 and the encapsulation layer ENCAP. That is, in the display area DA, the pixel electrode PE, the emission layer EL, and the common electrode CE may be disposed between the second planarization layer PLN2 and the encapsulation layer ENCAP. For example, the pixel electrode PE may be an anode electrode, and the common electrode CE may be a cathode electrode. Conversely, the pixel electrode PE may be a cathode electrode, and the common electrode CE may be an anode electrode.

In the display area DA, the pixel electrode PE on the second planarization layer PLN2 may be electrically connected to a source node or a drain node of the driving transistor DRT positioned under the first planarization layer PLN1 through the through-holes of the second planarization layer PLN2 and the first planarization layer PLN1.

Referring to FIGS. 7 to 9, the encapsulation layer ENCAP may extend from the display area DA and may also be disposed in the non-display area NDA.

The encapsulation layer ENCAP may include an organic encapsulation layer PCL.

The encapsulation layer ENCAP may further include a first inorganic encapsulation layer PAS1 positioned under the organic encapsulation layer PCL and a second inorganic encapsulation layer PAS2 positioned on the organic encapsulation layer PCL.

Referring to FIGS. 7 to 9, the display panel 110 may further include a first dam DAM1 and a second dam DAM2 disposed in the dam area DAMA.

The first dam DAM1 may be disposed in the non-display area NDA, and may be located near or outside the inclined surface SLP of the encapsulation layer ENCAP. The second dam DAM2 may be disposed in the non-display area NDA, and may be located more outside than the first dam DAM1.

Referring to FIGS. 7 to 9, the organic encapsulation layer PCL may be positioned on an inner side surface of the first dam DAM1. That is, the organic encapsulation layer PCL may be positioned in an inner area positioned on the inner side surface of the first dam DAM1. At least one of the first inorganic encapsulation layer PAS1 and the second inorganic encapsulation layer PAS2 may extend from an inner side area of the first dam DAM1 and be disposed along an upper portion of the first dam DAM1.

According to the example of FIG. 7, the first inorganic encapsulation layer PAS1 may be disposed to pass over the first dam DAM1 and the second dam DAM2 and extend outside the second dam DAM2. The second inorganic encapsulation layer PAS2 may also be disposed in the same manner as the first inorganic encapsulation layer PAS1. The second inorganic encapsulation layer PAS2 may be disposed on the first inorganic encapsulation layer PAS1. The second inorganic encapsulation layer PAS2 may be disposed to pass over the first dam DAM1 and the second dam DAM2 and extend outside the second dam DAM2. The second inorganic encapsulation layer PAS2 may pass through an upper portion of the first dam DAM1, a valley formed between the first dam DAM1 and the second dam DAM2, and an upper portion of the second dam DAM2, and may extend to the outside of the second dam DAM2. Likewise, the first inorganic encapsulation layer PAS1 may pass through an upper portion of the first dam DAM1, a valley formed between the first dam DAM1 and the second dam DAM2, and an upper portion of the second dam DAM2, and may extend to the outside of the second dam DAM2.

The first inorganic encapsulation layer PAS1 may be formed on a common electrode (e.g., a cathode electrode) to be closest to the light emitting device ED. For example, the first inorganic encapsulation layer PAS1 may be formed of an inorganic insulating material capable of low-temperature deposition, such as silicon nitride (SiNx), silicon oxide (SiOx), silicon oxynitride (SiON), or aluminum oxide (Al2O3). Accordingly, since the first inorganic encapsulation layer PAS1 is deposited in a low temperature atmosphere, it is possible to prevent damage to the light emitting layer EL, which is vulnerable to a high temperature atmosphere, during the deposition process of the first inorganic encapsulation layer PAS1.

The organic encapsulation layer PCL may have a smaller area than the first inorganic encapsulation layer PAS1. In this case, the first inorganic encapsulation layer PAS1 may be disposed to extend to the outside of the organic encapsulation layer PCL. The organic encapsulation layer PCL may serve as a buffer for relieving stress between layers due to bending of the display device 100, which is an organic light emitting display device, and may serve to enhance planarization performance. For example, the organic encapsulation layer PCL may be an acrylic resin, an epoxy resin, polyimide, polyethylene, or silicon oxycarbon (SiOC), and may be formed of an organic insulating material. For example, the organic encapsulation layer PCL may be formed through an inkjet method.

The second inorganic encapsulation layer PAS2 may be positioned on the organic encapsulation layer PCL, and may be formed to cover an upper surface and a side surface of each of the organic encapsulation layer PCL and the first inorganic encapsulation layer PAS1.

Accordingly, the second inorganic encapsulation layer PAS2 may minimize or block the penetration of external moisture or oxygen into the first inorganic encapsulation layer PAS1 and the organic encapsulation layer PCL. For example, the second inorganic encapsulation layer PAS2 may include an inorganic insulating material such as silicon nitride (SiNx), silicon oxide (SiOx), silicon oxynitride (SiON), or aluminum oxide (Al2O3).

When the liquid organic encapsulation layer PCL is dropped on the display area DA during the process, the first dam DAM1 and the second dam DAM2 may prevent the liquid organic encapsulation layer from collapsing in the direction of the non-display area NDA and encroaching on the touch pad unit TP or the like.

Referring to FIGS. 7 to 9, the display panel 110 may include a bezel circuit layer BCL on a substrate SUB. The bezel circuit layer BCL may be positioned between the substrate SUB and the transistor forming layer, and may be positioned in the non-display area NDA.

In the bezel circuit layer BCL, an outer power line VLA and a panel built-in gate driving circuit GIPA may be positioned.

Referring to FIGS. 7 to 9, the outer power line VLA may be disposed on the substrate SUB in the non-display area NDA, and may be located under the first dam DAM1 and the second dam DAM2. The outer power line VLA may overlap the first dam DAM1 and the second dam DAM2.

Referring to FIGS. 7 to 9, the display panel 110 of the display device 100 according to aspects of the present disclosure may further include a surrounding organic pattern SOP positioned between the first dam DAM1 and the second dam DAM2.

Referring to FIGS. 7 to 9, in the display panel 110 according to aspects of the present disclosure, the surrounding organic pattern SOP may be positioned on the second inorganic encapsulation layer PAS2.

Referring to FIGS. 7 to 9, the surrounding organic pattern SOP may be positioned on the second inorganic encapsulation layer PAS2, and may be positioned in a valley formed between the first dam DAM1 and the second dam DAM2.

Referring to FIGS. 7 to 9, the surrounding organic pattern SOP may overlap at least one of the first inorganic encapsulation layer PAS1 and the second inorganic encapsulation layer PAS2.

Referring to FIGS. 7 to 9, the surrounding organic pattern SOP may overlap the outer power line VLA. At least one insulating layer INS may be disposed between the surrounding organic pattern SOP and the outer power line VLA.

For example, the outer power line VLA may include a base voltage line VSS Line that supplies a base voltage VSS applied to the common electrode CE of the light emitting devices ED.

As shown in FIGS. 7 to 9, as the surrounding organic pattern SOP is positioned between the first dam DAM1 and the second dam DAM2, another metal positioned above the surrounding organic pattern SOP may be insulated from the outer power line VLA positioned under the first dam DAM1 and the second dam DAM2. According to the insulating structure between the metal positioned on the surrounding organic pattern SOP and the outer power line VLA, it is possible to prevent a large amount of static electricity from being generated in the outer power line VLA or the occurrence of insulation breakdown.

Accordingly, a film lifting phenomenon or moisture permeation phenomenon in the periphery of the outer power line VLA caused by static electricity or dielectric breakdown in the outer power line VLA may be prevented in advance.

Referring to FIGS. 7 to 9, the panel built-in gate driving circuit GIPA may be located in the bezel circuit layer BCL on the substrate SUB. The panel built-in gate driving circuit GIPA may be located on the inner side of the outer power line VLA. The panel built-in gate driving circuit GIPA may be a gate in panel (GIP) type gate driving circuit 130. The panel built-in gate driving circuit GIPA is also called a panel-embedded gate driving circuit.

Referring to FIGS. 7 to 9, the display panel 110 according to aspects of the present disclosure may further include a touch sensor metal TSM positioned on the second inorganic encapsulation layer PAS2, and a touch routing line TL located on the second inorganic encapsulation layer PAS2 and extending from the touch sensor metal TSM or electrically connected to the touch sensor metal TSM.

Referring to FIGS. 7 to 9, the touch routing line TL may extend from the touch sensor metal TSM or may be electrically connected to the touch sensor metal TSM, may extend to the non-display area NDA, and may be electrically connected to the touch pad unit TP positioned outside the non-display area NDA. Here, the touch pad unit TP may be electrically connected to the touch driving circuit 160 and located outside the non-display area NDA.

Referring to FIGS. 7 to 9, the touch routing line TL may be disposed along the inclined surface SLP of the second inorganic encapsulation layer PAS2 and may be electrically connected to the touch pad unit TP located in the outer region of the second inorganic encapsulation layer PAS2.

Referring to FIGS. 7 to 9, the touch routing line TL may overlap the surrounding organic pattern SOP.

As shown in FIGS. 7 to 9, as the surrounding organic pattern SOP is positioned between the first dam DAM1 and the second dam DAM2, an insulating structure may be formed between the outer power line VLA positioned under the first dam DAM1 and the second dam DAM2 and the touch routing line TL positioned above the surrounding organic pattern SOP. According to the insulating structure, it is possible to prevent a lot of static electricity from being generated in the outer power line VLA or breakdown of insulation from occurring.

Accordingly, film lifting or moisture permeation caused by static electricity or dielectric breakdown in the outer power line VLA may be prevented in advance. The film lifting phenomenon may be a phenomenon in which a layer (e.g., insulating layer, substrate, or buffer layer, etc.) positioned around the outer power line VLA is lifted. The moisture permeation phenomenon may be a phenomenon in which moisture permeates into a layer (e.g., insulating layer, substrate, or buffer layer, etc.) positioned around the outer power line VLA. For example, the layer positioned around the outer power line VLA may include an insulating layer INS, a substrate SUB, a PI substrate, or a buffer layer.

As shown in FIGS. 7 to 9, as the surrounding organic pattern SOP is positioned between the first dam DAM1 and the second dam DAM2, an electrical influence of the power (e.g., VSS) from the outer power line VLA on the touch routing line TL above the first dam DAM1 and the second dam DAM2 may be reduced or blocked.

Referring to FIGS. 7 to 9, the display panel 100 may further include a touch inorganic layer T-BUF. The touch inorganic layer T-BUF may be disposed on the second inorganic encapsulation layer PAS2 and may extend along upper portions of the first dam DAM1 and the second dam DAM2.

The touch inorganic layer T-BUF may partially overlap the surrounding organic pattern SOP.

The touch sensor metal TSM may be disposed on the touch inorganic layer T-BUF.

The touch inorganic layer T-BUF is an optional layer, and may or may not be on the encapsulation layer ENCAP.

When the touch inorganic layer T-BUF is present, the touch inorganic layer T-BUF may be disposed on the encapsulation layer ENCAP, and the touch sensor metal TSM may be disposed on the touch inorganic layer T-BUF.

In the absence of the touch inorganic layer T-BUF, the touch sensor metal TSM may be directly disposed on the encapsulation layer ENCAP.

The touch inorganic layer T-BUF may be positioned between the touch sensor metal TSM and the common electrode CE. Depending on the presence and thickness of the touch inorganic layer T-BUF, the separation distance between the touch sensor metal TSM and the common electrode CE may be designed to maintain a predetermined minimum separation distance (e.g., 5 μm). Accordingly, it is possible to reduce or prevent the parasitic capacitance between the touch sensor metal TSM and the common electrode CE. By reducing and preventing parasitic capacitance, touch sensitivity may be improved.

During the manufacturing process of the touch sensor, a chemical solution (developer or etchant, etc.) used in the process or moisture from the outside may be generated. By disposing the touch inorganic layer T-BUF and disposing the touch sensor thereon, it is possible to prevent the chemical solution or moisture from penetrating into the light emitting layer EL including an organic material during the manufacturing process of the touch sensor. Accordingly, the touch inorganic layer T-BUF may prevent damage to the light emitting layer EL, which is vulnerable to the chemical solution or moisture.

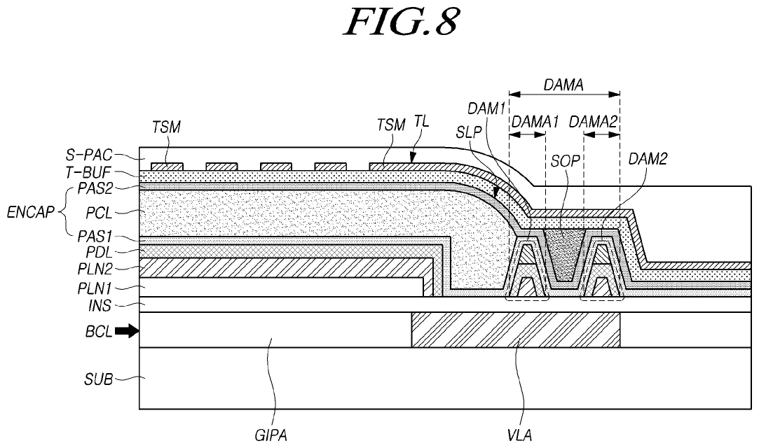

Referring to FIG. 8, the display panel 110 may further include a sensor protective layer S-PAC. The sensor protective layer S-PAC may be disposed on the touch sensor metal TSM and may partially overlap the surrounding organic pattern SOP.

For example, the sensor protective layer S-PAC may be an organic layer.

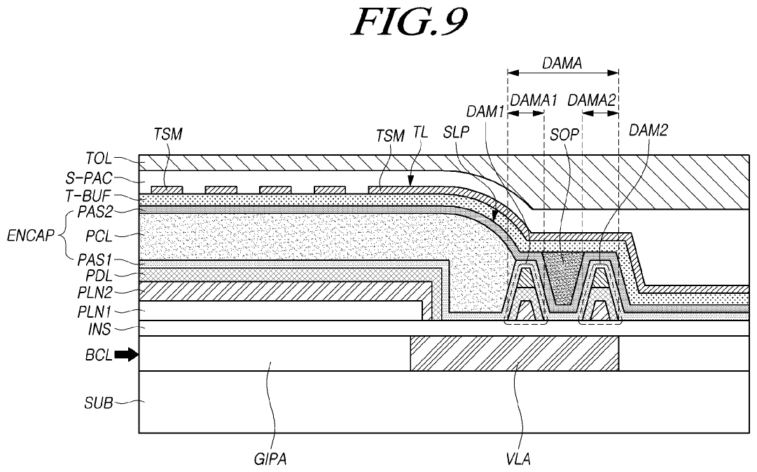

Referring to FIG. 9, the display panel 110 may further include a top organic layer TOL positioned on the sensor protective layer S-PAC and partially overlapping the surrounding organic pattern SOP.

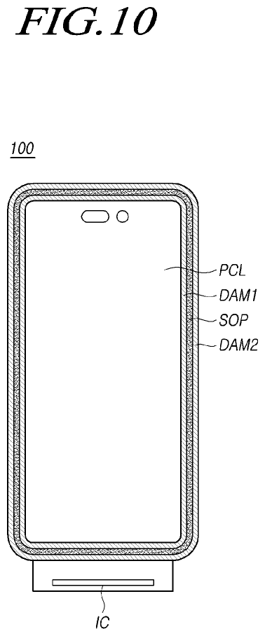

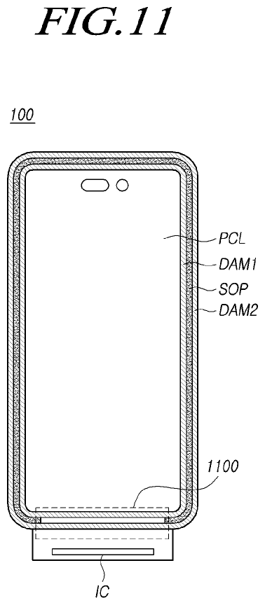

FIGS. 10 and 11 show planar structures of the surrounding organic pattern SOP of the display device 100 according to aspects of the present disclosure.

The display device 100 according to aspects of the present disclosure may include a substrate SUB including a display area DA and a non-display area NDA positioned outside the display area DA, light emitting elements EA disposed in the display area DA, and an encapsulation layer ENCAP disposed on the light emitting elements EA and including an organic encapsulation layer PCL. Referring to FIGS. 10 and 11, the display device 100 according to aspects of the present disclosure may include a surrounding organic pattern SOP disposed in the non-display area NDA along the periphery of the organic encapsulation layer PCL and surrounding all or a part of the organic encapsulation layer PCL.

Referring to FIGS. 10 and 11, in the display device 100 according to aspects of the present disclosure, each of the first dam DAM1 and the second dam DAM2 may be of a ring type disposed in the non-display area NDA along the outer edge of the display area DA.

Referring to FIG. 10, the surrounding organic pattern SOP may be disposed in the non-display area NDA along the periphery of the organic encapsulation layer PCL. The surrounding organic pattern SOP may be a closed ring type organic layer. The surrounding organic pattern SOP may be disposed to completely surround the organic encapsulation layer PCL in all directions.

Referring to FIG. 10, the surrounding organic pattern SOP may be disposed in the non-display area NDA along the periphery of the display area DA. The surrounding organic pattern SOP may be a closed ring type organic layer and may be disposed to completely surround the display area DA.

Referring to FIG. 11, the surrounding organic pattern SOP may be disposed in the non-display area NDA along the periphery of the organic encapsulation layer PCL. The surrounding organic pattern SOP may be an open ring type organic layer surrounding the organic encapsulation layer PCL. The surrounding organic pattern SOP may be disconnected at a circuit connection area 1100 to which the integrated circuit IC is bonded or electrically connected. The surrounding organic pattern SOP may have a U-shape in which a break point exists. The open ring type is also referred to as the U type.

Referring to FIG. 11, the surrounding organic pattern SOP may be disposed in the non-display area NDA along the periphery of the display area DA. The surrounding organic pattern SOP may be an open ring type organic layer surrounding the display area DA. The surrounding organic pattern SOP may be disconnected near a circuit connection area 1100 to which the integrated circuit IC is bonded or electrically connected.

According to the aspects of the present disclosure, it is possible to provide a display device having a structure capable of blocking a film lifting phenomenon and a moisture permeation defect caused by static electricity in advance.

According to aspects of the present disclosure, by blocking or reducing the influence of static electricity on the outer power line VLA through the surrounding organic pattern SOP, the outer power line VLA may be less affected by static electricity.

Accordingly, the film lifting phenomenon in which the film (layer) located in the periphery of the outer power line VLA is lifted due to static electricity may be blocked in advance, and moisture permeation defect in the vicinity where the film lifting phenomenon has occurred may be blocked in advance.

An area in the non-display area NDA without the organic encapsulation layer PCL, which is an organic layer, may be an area in which a film lifting phenomenon due to static electricity is highly likely to occur. By disposing the surrounding organic pattern SOP as an organic layer between the first dam DAM1 and the second dam DAM2 in the area where the organic encapsulation layer PCL is not present, in the area where the organic encapsulation layer PCL is not present, the film lifting phenomenon may be prevented.

According to the aspects of the present disclosure, it is possible to provide a display device capable of blocking in advance a film lifting phenomenon and a moisture permeation defect under a narrow bezel structure. That is, according to aspects of the present disclosure, it is possible to block the film lifting phenomenon and the moisture permeation defect without increasing the size of the bezel.

According to the aspects of the present disclosure, it is possible to provide a display device 100 having a structure that can prevent film lifting and moisture permeation defects around the outer power line VLA due to static electricity in advance by preventing the outer power line VLA from being affected by static electricity.

According to the aspects of the present disclosure, it is possible to provide the display device 100 having a structure that can increase insulation between the touch routing line TL extended from the touch sensor metal TSM or connected to the touch sensor metal TSM and the outer power line VLA.

The aspects of the present disclosure described above will be briefly described below.

The display device according to an aspect of the present disclosure includes a substrate including a display area and a non-display area positioned outside the display area, a plurality of light emitting devices disposed in the display area, an encapsulation layer disposed on the plurality of light emitting devices and including an organic encapsulation layer, and a surrounding organic pattern disposed in the non-display area along an outer periphery of the organic encapsulation layer and surrounding all or part of the organic encapsulation layer.

In the display device according to an aspect of the present disclosure, the surrounding organic pattern may be disposed in the non-display area along the periphery of the organic encapsulation layer, and may be a closed ring type organic layer. The surrounding organic pattern may surround the organic encapsulation layer in all directions.

In the display device according to an aspect of the present disclosure, the surrounding organic pattern may be an open ring type organic layer disposed in the non-display area along the periphery of the organic encapsulation layer and surrounding the organic encapsulation layer. The surrounding organic pattern may surround a portion of the organic encapsulation layer, and may be disconnected at a circuit connection area to which an integrated circuit is bonded or electrically connected.

The display device according to an aspect of the present disclosure may further include a first dam disposed in the non-display area and located near or outside an inclined surface of the encapsulation layer, and a second dam disposed in the non-display area and positioned outside the first dam.

In the display device according to an aspect of the present disclosure, the encapsulation layer may further include a first inorganic encapsulation layer positioned under the organic encapsulation layer and a second inorganic encapsulation layer positioned on the organic encapsulation layer.

In the display device according to an aspect of the present disclosure, the organic encapsulation layer may be positioned on an inner side surface of the first dam.

In the display device according to an aspect of the present disclosure, at least one of the first inorganic encapsulation layer and the second inorganic encapsulation layer may extend from an inner side area of the first dam and may be disposed along an upper portion of the first dam.

In the display device according to an aspect of the present disclosure, the surrounding organic pattern may overlap at least one of the first inorganic encapsulation layer and the second inorganic encapsulation layer.

In the display device according to an aspect of the present disclosure, the surrounding organic pattern may be positioned on the second inorganic encapsulation layer.

In the display device according to an aspect of the present disclosure, the surrounding organic pattern may be positioned between the first dam and the second dam.

In the display device according to an aspect of the present disclosure, the second inorganic encapsulation layer may extend beyond the upper portion of the first dam, a valley formed between the first dam and the second dam, and an upper portion of the second dam to an outer edge of the second dam.

In the display device according to an aspect of the present disclosure, the surrounding organic pattern may be located on the second inorganic encapsulation layer, and may be located in the valley formed between the first dam and the second dam.

The display device according to an aspect of the present disclosure may further include a touch sensor metal positioned on the second inorganic encapsulation layer, a touch routing line positioned on the second inorganic encapsulation layer and extending from the touch sensor metal or electrically connected to the touch sensor metal, and a touch pad unit electrically connected to a touch driving circuit and positioned outside the non-display area.

In the display device according to an aspect of the present disclosure, the touch routing line may be disposed along an inclined surface of the second inorganic encapsulation layer and is electrically connected to the touch pad unit, and the touch routing line may overlap the surrounding organic pattern.

The display device according to an aspect of the present disclosure may further include a touch inorganic layer positioned on the second inorganic encapsulation layer. The touch inorganic layer may be disposed to extend along upper portions of the first dam and the second dam, and partially overlaps the surrounding organic pattern.

The display device according to an aspect of the present disclosure may further include a sensor protective layer positioned on the touch sensor metal and partially overlapping the surrounding organic pattern.

The display device according to an aspect of the present disclosure may further include a top organic layer positioned on the sensor protective layer and partially overlapping the surrounding organic pattern.

The display device according to an aspect of the present disclosure may further include an outer power line disposed on the substrate in the non-display area, positioned under the first dam and the second dam, and overlapping the first dam and the second dam.

The display device according to an aspect of the present disclosure may further include at least one insulating layer disposed between the surrounding organic pattern and the outer power line. The surrounding organic pattern overlaps the outer power line.

In the display device according to an aspect of the present disclosure, the outer power line may include a base voltage line for supplying a base voltage applied to a common electrode.

The display device according to an aspect of the present disclosure may further include a gate driving circuit of a Gate In Panel (GIP) type positioned on an inner side of the outer power line and located in a bezel circuit layer on the substrate.

In the display device according to an aspect of the present disclosure, each of the first dam and the second dam may be a ring type disposed in the non-display area along an outer edge of the display area.

In the display device according to an aspect of the present disclosure, the surrounding organic pattern may be disposed on the non-display area along an outer edge of the display area, and the surrounding organic pattern may be a closed ring type organic layer and may completely surround the display area.

In the display device according to an aspect of the present disclosure, the surrounding organic pattern may be disposed on the non-display area along an outer edge of the display area, and the surrounding organic pattern may be an open ring type organic layer, and may be disconnected at a circuit connection area to which an integrated circuit is bonded or electrically connected.

The display device according to an aspect of the present disclosure includes a substrate including a display area and a non-display area positioned outside the display area, a common electrode disposed on the substrate, an encapsulation layer disposed on the common electrode, a first dam disposed in the non-display area and located near or outside the inclined surface of the encapsulation layer, a second dam disposed in the non-display area and positioned outside the first dam, and a surrounding organic pattern positioned between the first dam and the second dam.

The display device according to an aspect of the present disclosure may further include an outer power line disposed on the substrate in the non-display area and overlapping the first dam and the second dam.

The display device according to an aspect of the present disclosure may further include at least one insulating layer disposed between the surrounding organic pattern and the outer power line. The surrounding organic pattern overlaps the outer power line.

In the display device according to an aspect of the present disclosure, the outer power line may include a base voltage line for supplying a base voltage applied to the common electrode.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. The above description and the accompanying drawings provide an example of the technical idea of the present disclosure for illustrative purposes only. That is, the disclosed aspects are intended to illustrate the scope of the technical idea of the present disclosure. Thus, the scope of the present disclosure is not limited to the aspects shown, but is to be accorded the widest scope consistent with the claims. The scope of protection of the present disclosure should be construed based on the following claims, and all technical ideas within the scope of equivalents thereof should be construed as being included within the scope of the present disclosure.

What is claimed is:

1. A display device comprising:
a substrate including a display area and a non-display area positioned outside the display area;
a plurality of light emitting devices disposed in the display area;
an encapsulation layer disposed on the plurality of light emitting devices and including an organic encapsulation layer; and
a surrounding organic pattern disposed in the non-display area along an outer periphery of the organic encapsulation layer and surrounding at least a portion of the organic encapsulation layer.

2. The display device according to claim 1, wherein the surrounding organic pattern surrounds the organic encapsulation layer in all directions.

3. The display device according to claim 1, wherein the surrounding organic pattern is disconnected at a circuit connection area to which an integrated circuit is bonded or electrically connected.

4. The display device according to claim 1, further comprising:
a first dam disposed in the non-display area and located near or outside an inclined surface of the encapsulation layer; and
a second dam disposed in the non-display area and positioned outside the first dam,
wherein the encapsulation layer further includes a first inorganic encapsulation layer positioned under the organic encapsulation layer and a second inorganic encapsulation layer positioned on the organic encapsulation layer,
wherein the organic encapsulation layer is positioned on an inner side surface of the first dam,
wherein at least one of the first inorganic encapsulation layer and the second inorganic encapsulation layer extends from an inner side area of the first dam and is disposed along an upper portion of the first dam, and
wherein the surrounding organic pattern overlaps with at least one of the first inorganic encapsulation layer and the second inorganic encapsulation layer.

5. The display device according to claim 4, wherein the surrounding organic pattern is positioned on the second inorganic encapsulation layer.

6. The display device according to claim 4, wherein the surrounding organic pattern is positioned between the first dam and the second dam.

7. The display device according to claim 4, wherein the second inorganic encapsulation layer extends beyond the upper portion of the first dam, a valley formed between the first dam and the second dam, and an upper portion of the second dam to an outer edge of the second dam, and
wherein the surrounding organic pattern is located on the second inorganic encapsulation layer, and is located in the valley formed between the first dam and the second dam.

8. The display device according to claim 4, further comprising:
a touch sensor metal positioned on the second inorganic encapsulation layer;
a touch routing line positioned on the second inorganic encapsulation layer and extending from the touch sensor metal or electrically connected to the touch sensor metal; and
a touch pad unit electrically connected to a touch driving circuit and positioned outside the non-display area,
wherein the touch routing line is disposed along an inclined surface of the second inorganic encapsulation layer and is electrically connected to the touch pad unit, and
wherein the touch routing line overlaps the surrounding organic pattern.

9. The display device according to claim 8, further comprising a touch inorganic layer positioned on the second inorganic encapsulation layer, wherein the touch inorganic layer is disposed to extend along upper portions of the first dam and the second dam, and overlaps the surrounding organic pattern.

10. The display device according to claim 8, further comprising a sensor protective layer positioned on the touch sensor metal and overlapping with the surrounding organic pattern.

11. The display device according to claim 10, further comprising a top organic layer positioned on the sensor protective layer and overlapping with the surrounding organic pattern.

12. The display device according to claim 4, further comprising:
an outer power line disposed on the substrate in the non-display area, positioned under the first dam and the second dam, and overlapping with the first dam and the second dam; and
at least one insulating layer disposed between the surrounding organic pattern and the outer power line,
wherein the surrounding organic pattern overlaps with the outer power line.

13. The display device according to claim 12, wherein the outer power line includes a base voltage line for supplying a base voltage applied to a common electrode.

14. The display device according to claim 12, further comprising a gate driving circuit of a Gate In Panel (GIP) type positioned on an inner side of the outer power line and located in a bezel circuit layer on the substrate.

15. The display device according to claim 4, wherein each of the first dam and the second dam is a ring type disposed in the non-display area along an outer edge of the display area.

16. The display device according to claim 1, wherein the surrounding organic pattern is disposed on the non-display area along an outer edge of the display area, and
wherein the surrounding organic pattern is a closed ring type organic layer and surrounds the display area.

17. The display device according to claim 1, wherein the surrounding organic pattern is disposed on the non-display area along an outer edge of the display area, and
wherein the surrounding organic pattern is an open ring type organic layer and is disconnected at a circuit connection area to which an integrated circuit is bonded or electrically connected.

18. A display device comprising:
a substrate including a display area and a non-display area positioned outside the display area;
a common electrode disposed on the substrate;
an encapsulation layer disposed on the common electrode;
a first dam disposed in the non-display area and located near or outside the inclined surface of the encapsulation layer;
a second dam disposed in the non-display area and positioned outside the first dam; and
a surrounding organic pattern positioned between the first dam and the second dam.

19. The display device according to claim 18, further comprising:
an outer power line disposed on the substrate in the non-display area and overlapping with the first dam and the second dam; and
at least one insulating layer disposed between the surrounding organic pattern and the outer power line,
wherein the surrounding organic pattern overlaps with the outer power line.

20. The display device according to claim 19, wherein the outer power line includes a base voltage line for supplying a base voltage applied to the common electrode.

21. A display device comprising:
a substrate including a display area and a non-display area positioned outside the display area;
a plurality of light emitting devices disposed in the display area;
an encapsulation layer disposed on the plurality of light emitting devices and including an organic encapsulation layer;
a surrounding organic pattern disposed in the non-display area along an outer periphery of the organic encapsulation layer and surrounding at least a part of the organic encapsulation layer;
an outer power line disposed on the substrate in the non-display area and overlapping the surrounding organic pattern; and
at least one insulating layer disposed between the surrounding organic pattern and the outer power line.
